(19) United States
(12) Patent Application Publication
(10) Pub. No.: US 2013/0063631 A1
(43) Pub. Date: Mar. 14, 2013

(54) SOLID-STATE IMAGING APPARATUS AND CAMERA

(71) Applicants: Isao Hirota, Kanagawa (JP); Hirano Fujiki, Gumma (JP)

(72) Inventors: Tasuku Fujiki, Kanagwa (JP); Isao Hirota, Kanagawa (JP)

(73) Assignee: SONY CORPORATION, Tokyo (JP)

(21) Appl. No.: 13/410,367

(22) Filed: Mar. 2, 2012

(30) Foreign Application Priority Data
Mar. 10, 2011 (JP) 2011-052417

(51) Int. Cl. H01L 27/146; H04N 5/335

(52) U.S. Cl. 348/294; 257/291; 257/E27.133; 348/E05.091

(57) ABSTRACT

Disclosed herein is a solid-state imaging apparatus including a pixel cell separated by a device separation layer from a group of adjacent pixel cells by taking one pixel cell or a plurality of pixel cells as a unit wherein: the pixel cell has a first-conduction well, and a second-conduction well; the first-conduction well receives light and has an opto-electrical conversion function of carrying out an opto-electrical conversion process to convert the received light into electric charge as well as an electric-charge accumulation function for accumulating the electric charge; in the second-conduction well, a transistor is created to serve as a transistor used for detecting the electric charge accumulated in the first-conduction well and provided with a threshold modulation function.

### BACKGROUND

The present disclosure relates to an imaging apparatus having opto-electrical conversion devices and relates to a camera employing the imaging apparatus.

As already commonly known, in a solid-state imaging apparatus such as a CCD (charge-coupled device) image sensor or a CMOS (complementary metal-oxide semiconductor) image sensor, a crystal defect in a photodiode serving as an opto-electrical conversion device of the apparatus as well as a boundary-surface level on a boundary surface between a light receiving section and an insulation film provided on the light receiving section become sources generating dark currents.

As a method for effectively preventing a dark current from being generated by the boundary-surface level serving as one of the dark-current generation sources, there is provided a method in which the solid-state imaging apparatus is configured to adopt an embedded photodiode structure.

In the embedded photodiode, an n-type semiconductor area is typically created and, in the vicinity of the surface of the n-type semiconductor area, that is, in the vicinity of the surface of a boundary with an insulation film, a p-type semiconductor area having a large impurity concentration is shallowly created to serve as an area for preventing a dark current from being generated. The p-type semiconductor area is also referred to as a hole accumulation area.

In accordance with a method for making the embedded photodiode, in general, B and/or BF₂ ions are injected to serve as impurities of a p-type semiconductor area prior to an annealing treatment and, then, the p-type semiconductor area is created in the vicinity of the surface of a boundary between an n-type semiconductor area forming the photodiode and an insulation film.

In addition, every pixel of a CMOS image sensor is created to include a photodiode and a variety of transistors such as read, reset and amplification transistors. A signal obtained as a result of an opto-electrical conversion process carried out by the photodiode is processed by these transistors. Over the pixels, a wiring layer is created. The wiring layer includes metal lines laid out to form several layers. On the wiring layer, color filters and on-chip lenses are created. Each or the color filters is used for filtering out light incident to a photodiode so as to exclude light having wavelengths other than wavelengths prescribed in advance. On the other hand, each of the on-chip lenses is used for converging light on a photodiode.

As the CMOS image sensor having the configuration described above, there have been proposed device structures having a variety of characteristics.

For structures of opto-electrical conversion devices, there have been proposed structures of a variety of devices such as a CMD (Charge Modulation Device) having CCD characteristics and a BCMD (Bulk Charge Modulation Device). For more information on the CMD, the reader is advised to refer to documents such as Japanese Patent No. 1,938,092, Japanese Patent Laid-open No. Hei 6-120473, and Japanese Patent Laid-open No. Sho 60-140752, whereas, for more information on the BCMD, the reader is advised to refer to documents such as Japanese Patent Laid-open No. Sho 64-14959.

It is to be noted that each of these CMOS image sensors is basically a front-radiation solid-state imaging apparatus for receiving radiated light incident to the front surface of the device.

On the other hand, there has been also proposed a rear-surface-radiation solid-state imaging apparatus for receiving light from the rear surface of a silicon substrate and converting the light into an electrical signal. The rear-surface-radiation solid-state imaging apparatus is made by polishing the rear side of the silicon substrate on which a photodiode and a variety of transistors have been created for every pixel to produce a thin film from the substrate. The rear-surface-radiation solid-state imaging apparatus is also referred to as a back-surface-radiation solid-state imaging apparatus. For more information on the rear-surface-radiation solid-state imaging apparatus, the reader is advised to refer to documents such as Japanese Patent Laid-open No. Hei 10-65138.

By the way, as a solid-state imaging apparatus having the CMD structure, there are known a double-carrier CMD and a single-carrier CMD. For more information on the double-carrier CMD, the reader is advised to refer to documents such as “A New MOS Image Sensor Operating in a Non-destructive Readout Mode (IEDM 1986)” whereas, for more information on the single-carrier CMD, the reader is advised to refer to documents such as Japanese Patent Laid-open No. 2009-152234.

In these solid-state imaging apparatus having the CMD structure, an operation to output residual charge of an embedded sensor serving as an opto-electrical conversion section is explained below. The operation to output residual charge is also referred to as a reset operation.

In the double-carrier CMD, a voltage is applied to a substrate in order to lower a barrier between a sensor and the substrate so that electric charge accumulated in the sensor is thrown out to the substrate. In this way, a reset operation is carried out.

In the single-carrier CMD, on the other hand, the gate of a read transistor is used to modulate a sensor drain barrier referred to hereafter as an overflow barrier so as to lower the barrier. In this way, a reset operation can be carried out.

### SUMMARY

In the single-carrier CDM described above, however, if the overflow barrier is high so that a voltage required for the reset operation is also high as well, a large electric field is generated in a pinch-off area at a reset time so that it is quite within the bounds of possibility that a problem of reliability is raised.

In order to alleviate the electric field generated in the pinch-off area, a transistor is designed to have a structure in which the gate of the transistor is divided in a simple way as is the case with a high-voltage withstanding transistor disclosed in documents such as Japanese Patent Laid-open No. Sho 64-7460. If the transistor is designed to have such a structure, however, a dip and/or a barrier are formed in the separation area so that there is a bad effect on linearity.

It is thus an aim of the present disclosure to provide a solid-state imaging apparatus capable of lowering the overflow barrier, lowering the reset voltage, preventing an electric field from being generated in the pinch-off area, preventing a dip and/or a barrier from being generated in the channel and preventing the linearity from deteriorating. In addition, it is another aim of the present disclosure to provide a camera employing the solid-state imaging apparatus.

In accordance with a first embodiment of a technology given by the present disclosure, there is provided a solid-state imaging apparatus having a pixel cell separated by a device separation layer from a group of adjacent pixel cells by taking one pixel cell or a plurality of pixel cells as a unit. In the solid-state imaging apparatus:

the pixel cell has a first-conduction well and a second-conduction well;

the first-conduction well receives light and has an opto-electrical conversion function for carrying out an opto-electrical conversion process to convert the received light into electric charge as well as an electric-charge accumulation function for accumulating the electric charge;

in the second-conduction well, a transistor is created to serve as a transistor used for detecting the electric charge accumulated in the first-conduction well and provided with a threshold modulation function;

the transistor has a source, a drain as well as a gate electrode created in a channel creation area between the source and the drain; and

the gate electrode is divided into a main gate provided on a side close to the source and a sub-gate provided on a side close to the drain.

In accordance with a second embodiment of the technology given by the present disclosure, there is provided a camera having a solid-state imaging apparatus for receiving light from a first substrate surface side of a substrate and an optical system for guiding incident light to the first substrate surface side of the solid-state imaging apparatus. The solid-state imaging apparatus has a pixel cell separated by a device separation layer from a group of adjacent pixel cells by taking one pixel cell or a plurality of pixel cells as a unit. In the solid-state imaging apparatus:

the pixel cell has a first-conduction well and a second-conduction well;

the first-conduction well receives light and has an opto-electrical conversion function for carrying out an opto-electrical conversion process to convert the received light into electric charge as well as an electric-charge accumulation function for accumulating the electric charge;

in the second-conduction well, a transistor is created to serve as a transistor used for detecting the electric charge accumulated in the first-conduction well and provided with a threshold modulation function;

the transistor has a source, a drain as well as a gate electrode created in a channel creation area between the source and the drain; and

the gate electrode is divided into a main gate on the source side and a sub-gate on the drain side.

In accordance with the present disclosure, it is possible to lower the overflow barrier, lower the reset voltage and prevent an electric field from being generated in the pinch-off area. In addition, it is also possible to prevent a dip and/or a barrier from being generated in the channel and prevent the linearity from deteriorating.

### BRIEF DESCRIPTION OF THE DRAWINGS

FIG. 1 is a block diagram showing a rough configuration of a solid-state imaging apparatus according to an embodiment;

FIGS. 2A and 2B are a plurality of diagrams each showing the basic structure of a pixel section employed in the solid-state imaging apparatus according to the embodiment;

FIG. 3 is a diagram showing an equivalent circuit of a pixel cell according to the embodiment;

FIG. 4 is a diagram showing how the wavelength of incident light is related to the location of a transistor in the case of a front-radiation BMCD;

FIG. 5 is a diagram showing a rough state of an energy band created by a transparent electrode, a gate silicon oxide film and a silicon single crystal in the case of a front-surface radiation configuration;

FIG. 6 is a plurality of diagrams showing changes of an electric potential for an electron moving in a semiconductor substrate in a direction perpendicular to the surface of the semiconductor substrate in areas as electric-potential changes accompanying changes of an electric-potential state of the basic structure shown in FIGS. 2A and 2B as the basic structure of a pixel section employed in the solid-state imaging apparatus;

FIG. 7 is a simplified cross-sectional diagram showing a model of an ordinary single-carrier CMD;

FIG. 8 is a simplified cross-sectional diagram showing a model of the solid-state imaging apparatus according to the embodiment;

FIG. 9 is a diagram showing the profile of an electric potential between points a and a′ which are shown in FIG. 8;

FIG. 10 is a plurality of diagrams showing typical distributions of an electric potential along a line a-a′ shown in FIGS. 2A and 2B;

FIG. 11 is a diagram showing a model of the configuration of a signal read processing system according to the embodiment; and

FIG. 12 is a block diagram showing a typical configuration of a camera system employing the solid-state imaging apparatus according to the embodiment.

### DETAILED DESCRIPTION OF THE PREFERRED EMBODIMENTS

An embodiment of the present disclosure is explained by referring to the diagrams as follows. The embodiment is explained in description by dividing the description into topics arranged as follows:

1: Rough Configuration of the Solid-State Imaging Apparatus

2: Typical Device Structure of the Pixel Section

3: Camera

1: Rough Configuration of the Solid-State Imaging Apparatus

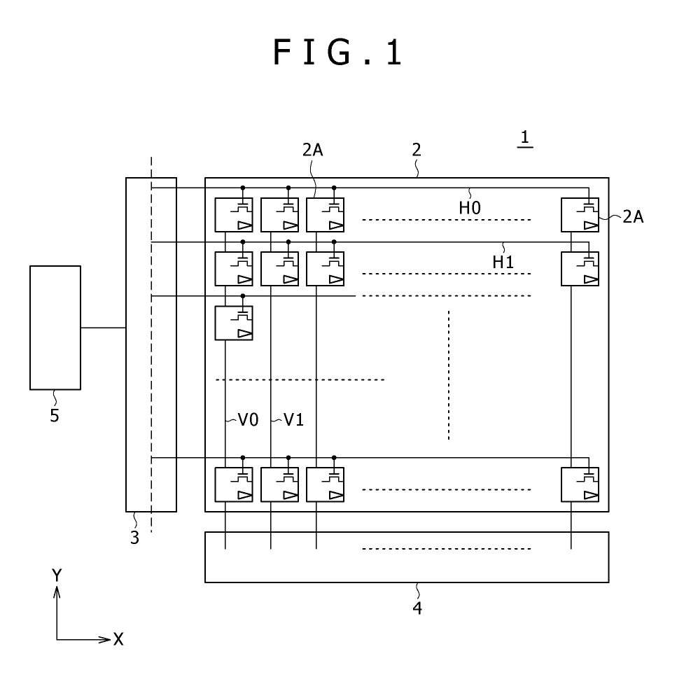

FIG. 1 is a block diagram showing a rough configuration of a solid-state imaging apparatus 1 according to an embodiment of the present disclosure.

As shown in FIG. 1, the solid-state imaging apparatus 1 employs a pixel section 2 serving as a sensing section, a row-direction control circuit 3 also referred to as a Y-direction control circuit, a column-direction control circuit 4 also referred to as an X-direction control circuit and a timing control circuit 5.

As will be described later in detail, the pixel section 2 is configured to employ a plurality of pixel cells 2A which are laid out to form a pixel matrix.

The pixel cells 2A employed in the pixel section 2 according to the embodiment are configured to function as an image sensor adopting a double-well structure, a threshold modulation (or CMD) method and rear-surface radiation configuration (or back-surface radiation configuration).

In addition, the pixel section 2 according to the embodiment adopts a double-well structure in which accumulated electric charge has the same carriers as a channel current. On top of that, every pixel cell 2A employed in the pixel section 2 according to the embodiment adopts a 1-transistor architecture also referred to as a 1-transistor structure in which one transistor carries out the functions of a read transistor, a reset transistor and a select transistor which would be otherwise included in every pixel cell 2A.

This transistor employed in the pixel cell 2A to serve as a transistor for carrying out the functions of a read transistor, a reset transistor and a select transistor is designed into a configuration in which the gate electrode of this transistor employed in the pixel cell 2A is divided into a main gate on the source side and a sub-gate on the drain side. In addition, at least in a reset operation, an intermediate voltage is applied to the sub-gate on the drain side. The intermediate voltage is a voltage between a voltage applied to the main gate on the source side and a voltage applied to the drain.

In addition, the sub-gate is created over a barrier between an embedded sensor and the drain of this transistor. The barrier is also referred to as the so-called overflow barrier.

On top of that, a narrow gap is created at a position between the main gate and the sub-gate. By adoption of a self-align technique or the like, ions are injected into a substrate in the gap in an operation referred to hereafter as an implantation.

In addition, pixel cells 2A laid out on the same row of the pixel matrix in the pixel section 2 are connected to a row line common to the pixel cells 2A. As shown in FIG. 1, row lines H0, H1 and so on are provided for respectively the rows of the pixel matrix. By the same token, pixel cells 2A laid out on the same column of the pixel matrix in the pixel section 2 are connected to a column line common to the pixel cells 2A. As shown in FIG. 1, column lines V0, V1 and so on are provided for respectively the columns of the pixel matrix.

On top of that, the solid-state imaging apparatus 1 employs control circuits for sequentially driving and receiving signals in the pixel section 2. The control circuits employed in the solid-state imaging apparatus 1 include the timing control circuit 5 for generating internal clock signals, the row-direction (Y-direction) control circuit 3 for controlling the row address as well as the row scanning and the column-direction (X-direction) control circuit 4 for controlling the column address as well as the column scanning.

The row-direction (Y-direction) control circuit 3 drives the predetermined row lines H0, H1 and so on in accordance with timing control pulses generated by the timing control circuit 5 as an internal clock signal cited above.

On the other hand, the column-direction (X-direction) control circuit 4 receives signals read out from the pixel cells 2A and asserted on the predetermined row lines V0, V1 and so on in accordance with timing control pulses generated by the timing control circuit 5 as an internal clock signal cited above. Then, the column-direction (X-direction) control circuit 4 carries out, among other processing, processing determined in advance and/or analog/digital conversion processing on the signals. The processing determined in advance includes CDS (Correlated Double Sampling).

2: Typical Device Structure of the Pixel Section

The following description explains the concrete device structure of the pixel section 2 employed in the solid-state imaging apparatus 1 according to the embodiment.

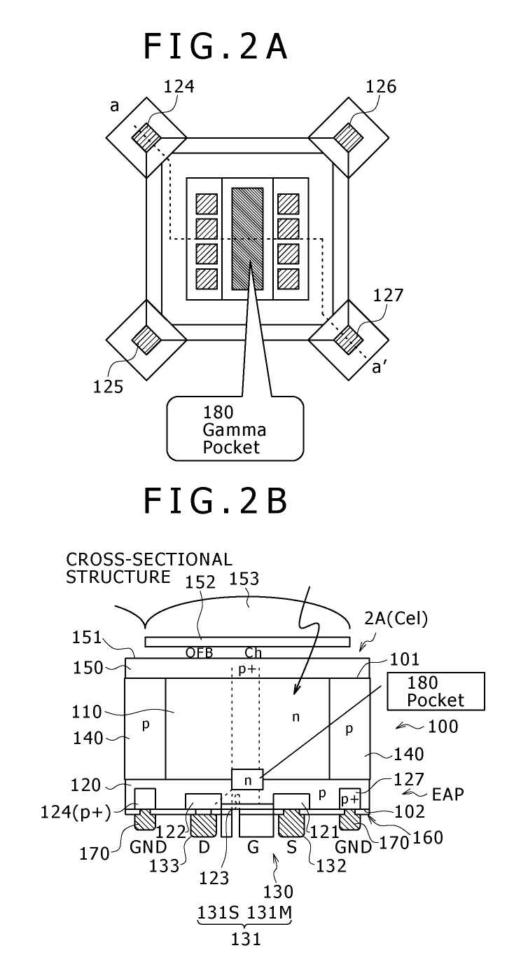

FIGS. 2A and 2B are a plurality of diagrams each showing the basic structure of the pixel section 2 employed in the solid-state imaging apparatus 1 according to the embodiment. To be more specific, FIG. 2A is a diagram showing the top view of the basic structure whereas FIG. 2B is a diagram showing a rough cross section seen along a line a-a′ shown in FIG. 2A as a cross section of the basic structure.

The solid-state imaging apparatus 1 is created as a rear-surface-radiation device or a back-surface-radiation device. As shown in FIG. 2B, incident light hits a first substrate surface 101 of an Si substrate 100. A second substrate surface 102 of the Si substrate 100 includes an EAP (element area portion) on which a MOS transistor is created. In the cross section shown in FIG. 2B, the first substrate surface 101 is the rear surface of the Si substrate 100 whereas the second substrate surface 102 is the front surface of the Si substrate 100.

In order to allow the incident light to enter the solid-state imaging apparatus 1 from the first substrate surface 101 serving as the rear surface of the Si substrate 100, the Si substrate 100 is created by producing a silicon wafer for making the Si substrate 100 as a thin film. The thickness of the Si substrate 100 depends on the type of the solid-state imaging apparatus 1. In addition, in the case of the visible light for example, the Si substrate 100 has a thickness in a range of 2 to 6 microns. In the case of the near-infrared light, on the other hand, the Si substrate 100 has a thickness in a range of 6 to 10 microns.

As described above, the Si substrate 100 has the first substrate surface 101 to which incident light is radiated and the second substrate surface 102 in which devices of the solid-state imaging apparatus 1 are created. In the Si substrate 100, a plurality of pixel cells 2A are created. Each of the pixel cells 2A is separated away from adjacent pixel cells 2A by a device separation layer.

Every pixel cell 2A in the Si substrate 100 according to the embodiment is separated by a device separation layer from a group of adjacent pixel cells 2A by taking one pixel cell 2A or a plurality of pixel cells 2A as a unit.

Every pixel cell 2A has a first-conduction well 110 created on the side close to the first substrate surface 101. In the case of this embodiment, the first-conduction well 110 is an n-type well. In the following description, the first-conduction well 110 is also referred to simply as a first well 110.

In addition, every pixel cell 2A has a second-conduction well 120 created on the side closer to the second substrate surface 102 than the first well 110 is closer to the second substrate surface 102. In the case of this embodiment, the second-conduction well 120 is a p-type well. In the following description, the second-conduction well 120 is also referred to simply as a second well 120.

The first well 110 of the n type functions as a light receiving section for receiving light from the side of the first substrate surface 101. In addition, the first well 110 also has an opto-electrical conversion function for converting the received light into electric charge. On top of that, the first well 110 also has an electric-charge accumulation function for accumulating the electric charge.

In the second well 120 of the p type, a MOS transistor 130 is created to serve as a transistor used for detecting the electric charge accumulated in the first-conduction well 110 serving as the light receiving section and provided with a threshold modulation function.

On the side walls of the first well 110, second-conduction device separation layers 140 each serving is a conduction layer are created to surround the side walls. In this embodiment, the second conduction is the p-type conduction which is the reverse of the n-type conduction taken as the first conduction as described earlier.

On the first substrate surface 101 used as the light-incidence surface of the Si substrate 100, a p⁺ layer 150 is created.

On the side close to the light-incidence surface of the p⁺ layer 150, an insulation film and/or a protection film 151 are created from typically a silicon oxide. In addition, on the protection film 151, a color filter 152 is created to serve as a filter for passing only light of a wavelength band determined in advance. On top of that, on the color filter 152, a micro-lens 153 is created to serve as a lens for converging light incident to the first-conduction well 110 serving as the light receiving section.

In the second well 120 of the p type, there are created a source area 121 and a drain area 122 which are separated from each other by a gap determined in advance. At a center between the source area 121 and the drain area 122, an n+ layer is created. A channel creation area 123 is created in the gap between the source area 121 and the drain area 122.

In addition, in a specific region in the second well 120, well contact areas 124 to 127 each also referred to as a substrate contact area are created as shown in FIG. 2A. Each of the well contact areas 124 to 127 is a p⁺ layer. The specific region in the second well 120 is a region not exposed to the first well 110. That is to say, the specific region in the second well 120 is composed of areas on the edges.

On top of that, an insulation film 160 made from a silicon oxide or the like is created selectively in a specific surface of the second substrate surface 102 of the Si substrate 100 by carrying out a process determined in advance. The specific surface of the second substrate surface 102 is a surface on which the source area 121, the drain area 122 and the well contact areas 124 to 127 are created.

In addition, on the channel creation area 123 between the source area 121 and the drain area 122 which are created on the side close to the second substrate surface 102 of the Si substrate 100, the gate electrode 131 of the MOS transistor 130 is created, being separated away from the second substrate surface 102 by the insulation film 160.

In this embodiment, the gate electrode 131 is divided into a main gate 131M on the source side and a sub-gate 131S on the drain side.

In addition, at least in a reset operation, an intermediate voltage of typically 1 V or 2 V is applied to the sub-gate 131S on the drain side. The intermediate voltage has a magnitude between a voltage applied to the main gate 131M on the source side and a voltage applied to the drain. The voltage applied to the main gate 131M has a magnitude in a range of 0 to −1.0 V whereas the voltage applied to the drain has a magnitude not smaller than 3 V. It is to be noted that the reset operation is an operation to discard electric charge to the drain area 122.

The sub-gate 131S is created over a barrier between the first well 110 serving as an embedded sensor and the drain area 122.

In addition, a narrow gap is created between mutually facing side walls of the sub-gate 131S and the main gate 131M and ions are injected into a substrate between the narrow gaps in the so-called injection of n-type ions.

On top of that, a hole is made through a portion of the insulation film 160 on the source area 121. The hole is used for creating a source electrode 132 connected to the source area 121 to serve as the source electrode 132 of the MOS transistor 130.

By the same token, a hole is made through a portion of the insulation film 160 on the drain area 122. The hole is used for creating a drain electrode 133 connected to the drain area 122 to serve as the drain electrode 133 of the MOS transistor 130.

In addition, a hole is made through a portion of the insulation film of each of the well contact areas 124 to 127. The holes are used for creating four well contact electrodes 170 connected to the well contact areas 124 to 127 respectively. The voltage applied to each of the well contact electrodes 170 is set typically at a level equal to the ground electric potential of 0 V or a level of −1.2 V.

In the configuration described above, the MOS transistor 130 is an insulation-gate field-effect transistor configured to include the source area 121, the drain area 122 and the channel creation area 123 which are created in the second well 120 on a side close to the second substrate surface 102.

In addition, the MOS transistor 130 is configured to also include the gate electrode 131, the source electrode 132 and the drain electrode 133 which are created on surface of the second substrate surface 102.

It is to be noted that, in the basic structure shown in FIGS. 2A and 2B as the basic structure of the pixel cell 2A, notation S denotes the source electrode 132 of the MOS transistor 130, notation D denotes the drain electrode 133 of the MOS transistor 130 whereas notation G denotes the gate electrode 131 of the MOS transistor 130.

As described above, the pixel cell 2A according to the embodiment is configured to function as an image sensor adopting rear-surface radiation configuration, a double-well structure and a threshold modulation (or CMD) method.

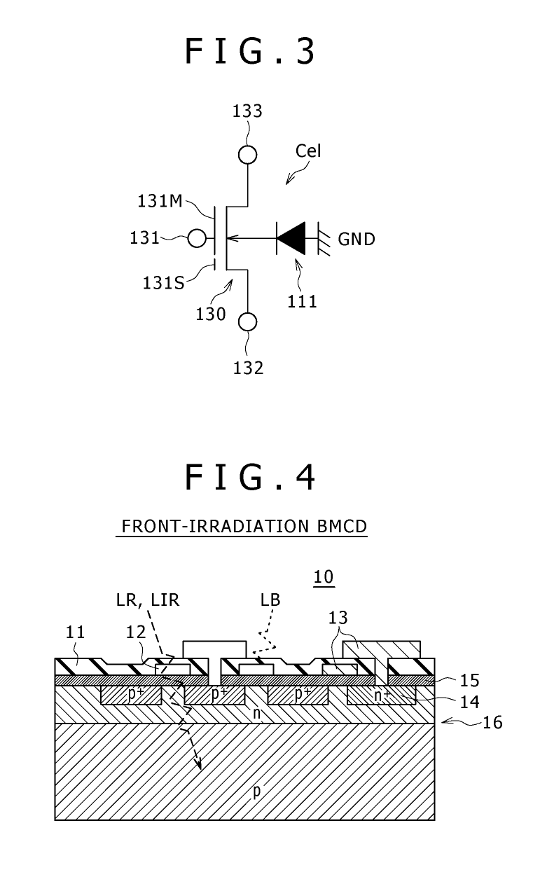

FIG. 3 is a diagram showing an equivalent circuit of a pixel cell 2A according to the embodiment.

As shown in FIG. 3, the pixel cell 2A is configured to employ an opto-electrical conversion and electric-charge accumulation device section 111 and the MOS transistor 130. The opto-electrical conversion and electric-charge accumulation device section 111 is a section created in the first well 110. The MOS transistor 130 has the gate electrode 131, the source electrode 132 and the drain electrode 133 which are created in the second well 120.

As described above, the pixel cell 2A according to the embodiment adopts a rear-surface radiation configuration and a double-well structure in which accumulated electric charge has the same carriers as a channel current. On top of that, the pixel cell 2A according to the embodiment adopts a 1-transistor architecture also referred to as a 1-transistor structure in which one transistor carries out the functions of a read transistor, a reset transistor and a select transistor which would be otherwise included in every pixel cell 2A.

That is to say, the embodiment adopts a rear-surface radiation configuration as well as a double-well structure and does not adopt a single-well modulation method for reasons described as follows.

If the single-well modulation method is adopted, pocket implantation for improving linearity is required. Thus, saturated electric charge Qs cannot be obtained anymore when the size of the pixel is reduced in an attempt to decrease an electric-charge accumulation area.

The single-well structure is not defect-proof and linearity pixel variations are very likely generated in the structure even though the degree of modulation and the conversion efficiency are high. If linearity pixel variations are generated, it is difficult to correct the variations.

In addition, pinning comes off in a read operation so that the compatibility with the column digital CDS is poor. If the analog CDS is adopted, an increase in capacitor area obstructs miniaturization efforts.

Even if the single-well modulation method is combined with the rear-surface radiation configuration, a reset transistor is required, entailing a 2-transistor configuration which is a disadvantage for the miniaturization efforts.

In the case of the embodiment, on the other hand, a rear-surface radiation configuration and the double-well structure are adopted. In addition, accumulated electric charge has the same carriers as a channel current. Only carriers having independent device separation are sufficient to make the embodiment capable of operating.

Thus, it is no longer necessary to provide a ring transistor structure. That is to say, it is possible to configure the MOS transistor 130 into the so-called one-direction structure including a drain (D), a gate (G) and a source (S) in the same way as an ordinary transistor.

In addition, the embodiment adopts a structure in which signal carriers are exhausted to the drain of the MOS transistor 130.

Thus, one transistor carries out the functions of a read (pick-up) transistor, a reset transistor and a select transistor to implement a perfect lateral reset structure with only one transistor.

That is to say, in accordance with the pixel-cell structure according to the embodiment, a 1-layer gate structure replacing a 2-layer gate structure is sufficient to make the embodiment capable of operating. Thus, special fine workmanship is not required for the device separation area.

In addition, it is possible to share a drain, a source and/or a gate with an adjacent pixel so that the layout efficiency is increased significantly and pixel miniaturization can be carried out.

On top of that, a lateral reset technique making use of the drain of the MOS transistor 130 is adopted. Thus, if the drain is implemented as a horizontal line and the horizontal line is used for each sharing pixel unit, a column can be shared by pixels so that a column circuit can be shrunk.

In addition, a free space is made available above the gate of the MOS transistor 130. Thus, in this free space, it is possible to provide a reflector structure making use of a wire metal to serve as the structure of a reflector. As a result, light passing through the Si (silicon) substrate is reflected by the reflector to be again subjected to an opto-electrical conversion process in the Si substrate so that it is possible to increase, among others, the near-infrared-light sensitivity.

On top of that, in the existing structure, the gate of the MOS transistor 130 is turned off during a light receiving period and the surface of the Si (silicon) substrate is put in a pinning state in order to let a dark current generated on a boundary surface recombine with holes. Thus, there is raised a problem that components not perfectly recombined become dark-current undulations and/or white-point defects.

On the other hand, the structure according to the embodiment is a double-well structure and, hence, dark-current electrons generated on the surface of the Si substrate can be exhausted from the channel to the drain. Thus, the structure according to the embodiment has a merit that a dark current generated on the boundary surface and white points can be perfectly shut out.

As a result, even if the gate is turned on at a column-read time, the dark current and the white points do not raise a problem so that a signal can be read out in a non-destructive read operation.

Next, the following description explains operations carried out in a pixel cell 2A having the configuration described above.

Incident light propagates from the first substrate surface 101 serving as a rear surface also referred to as a back surface to the inside of a pixel cell 2A, generating electron-hole pairs in the n-type first well 110 of the pixel cell 2A due to mainly a photoelectric effect. The generated holes are exhausted to the outside by way of a p-type device separation layer 140 forming a wall surface of the pixel cell 2A.

Thus, only the generated electrons are accumulated in the n-type first well 110. To be more specific, the generated electrons are accumulated in an electric-potential well created in the vicinity of a gate-area semiconductor surface between the source of the MOS transistor 130 and the drain thereof. Then, a signal of the accumulated electric charge is amplified and detected by the MOS transistor 130 before the accumulated electric charge is properly exhausted. In this way, a mixed color and/or the magnitude of a saturated current are controlled.

In addition, the semiconductor layer of the sensor employed in the solid-state imaging apparatus 1 has a thickness in a range of 2 to 10 microns. The thickness in this range is a thickness of an order allowing the quantization efficiency of the opto-electrical conversion process to be fully exhibited in the range of wavelengths of the incident light.

In the case of the front-surface-radiation configuration, on the other hand, the semiconductor substrate is normally required to have a thickness that hardly causes devices to be broken with ease. To put it concretely, the semiconductor substrate is required to have a thickness of several hundreds of microns. Thus, there may be raised a problem that a leak current flowing between the source and the drain through the substrate of the device cannot be ignored.

In the case of the embodiment, however, the device has a sufficiently small thickness. Thus, it is possible to reduce the magnitude of a leak current flowing through the substrate. As a result, the problem described above can be solved.

The configuration of the solid-state imaging apparatus 1 according to the embodiment and the functions of the apparatus 1 have been described so far. Next, the solid-state imaging apparatus 1 according to the embodiment is explained in detail as follows.

FIG. 4 is a diagram showing how the wavelength of incident light is related to the location of a transistor in the case of a front-surface radiation BMCD 10.

The front-surface radiation BMCD 10 shown in FIG. 4 is created to include an insulation film 11, a transparent electrode 12 and a light shielding electrode 13 which are provided on the front surface of a substrate. In the figure, reference numerals 14, 15 and 16 denote a lateral drain area, a gate insulation film and a silicon substrate respectively.

In the case of a front-surface radiation configuration shown in FIG. 4, light propagates from a side on which a transistor is provided. In this case, however, the lateral drain area 14 is covered by the light shielding electrode 13. Thus, the front-surface radiation BMCD 10 has a configuration in which light proceeds into the inside of the silicon substrate 16 from other apertures by way of, among others, the insulation film 11, the transparent electrode 12 and the gate insulation film 15.

Red light having a large wavelength and near-infrared light propagate from the surface of the silicon substrate, arriving at a relatively inner portion of the substrate. However, blue light and near-ultraviolet light are subjected to an opto-electrical conversion process at a location which is not that deep from the surface of the silicon substrate. In addition, when blue light having a small wavelength is passing through an insulation multi-layer film on the surface of the silicon substrate, the light is prone to an energy loss caused by scatterings and/or absorptions or reflections on a boundary surface.

In the case of the rear-surface radiation configuration shown in FIGS. 2A and 2B as a configuration based on the technology according to the present disclosure, on the other hand, the solid-state imaging apparatus 1 is designed into a structure in which light proceeds from a side on which the MOS transistor 130 is not provided into the inside of the silicon Si substrate 100. In this structure, most light beams each having a large wavelength arrive at locations in close proximity to the MOS transistor 130 and only very few light beams each having a small wavelength arrive at such locations.

In order to maximize the quantization efficiency including the wavelengths of incident light rays, there have been made a variety of proposals in areas of how to devise diffusion and well layers of the source and the drain.

However, there are only few discussions about possibilities that light passing through a silicon-oxide film serving as an insulation film has an effect on the characteristics of the transistor. The embodiment is explained also in order to briefly describe this possibility and clarify the mechanism of the effect even though the explanation of the embodiment is only a qualitative explanation.

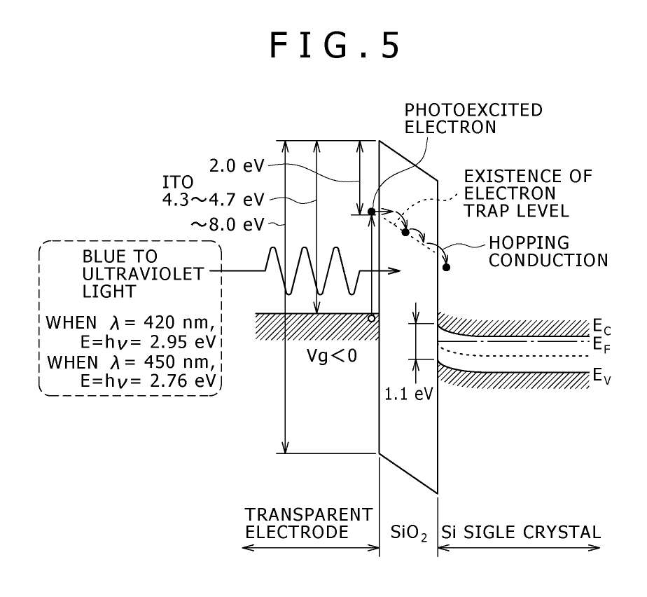

FIG. 5 is a diagram showing a rough state of an energy band created by a transparent electrode, a gate silicon oxide film and a silicon single crystal in the case of a front-surface radiation configuration.

The property of a gate silicon oxide film may vary much in some cases due to a method and processing which are adopted for making the film. If the method and the processing are not well controlled, a trap remains in the oxide film to serve as a trap for capturing electrons and holes. The figure shows a case in which a trap exists below the conduction band of the silicon oxide film to serve as a trap for capturing electrons at a position of 2.0 eV.

In the case of a silicon oxide film, the band gap is about 8.0 eV. If ITO is used as the transparent electrode, the work function is approximately in a range of 4.3 to 4.7 eV. Thus, the Fermi level of the transparent electrode is positioned at a location slightly beneath the center of the energy gap of the oxide film.

Here, attention is paid to a blue-color light component included in incident light as a component having a wavelength λ of typically 450 nm. In this case, from Einstein's light quantum equation E=hv, E is found to be 2.76 eV (that is, E=2.76 eV). As shown in the figure, the position of this energy is about equal to the position of the energy level measured from the Fermi level of the transparent electrode as the energy level of an electron trap in the oxide film.

At that time, if a relatively large negative voltage in comparison with the silicon substrate is applied to the transparent gate electrode, due to a photoelectric effect, an electron jumping out from a metal surface serving as the transparent electrode is excited in the oxide film and captured by the trap.

The electron captured by the trap is again released to electric charge to flow into the conduction band of a silicon crystal due to hopping conduction. Such flowing electrons result in a weak conductive state between the gate electrode and the silicon substrate, causing variations in transistor characteristic and signal magnitude.

In the rear-surface radiation configuration according to the embodiment, light having a large energy and a small wavelength has spent most of its energy in generation of photo carriers in the silicon substrate before the light attains a transistor area. Thus, the rear-surface radiation configuration according to the embodiment has a big characteristic that the configuration does not have the shortcomings like those of the front-surface radiation configuration.

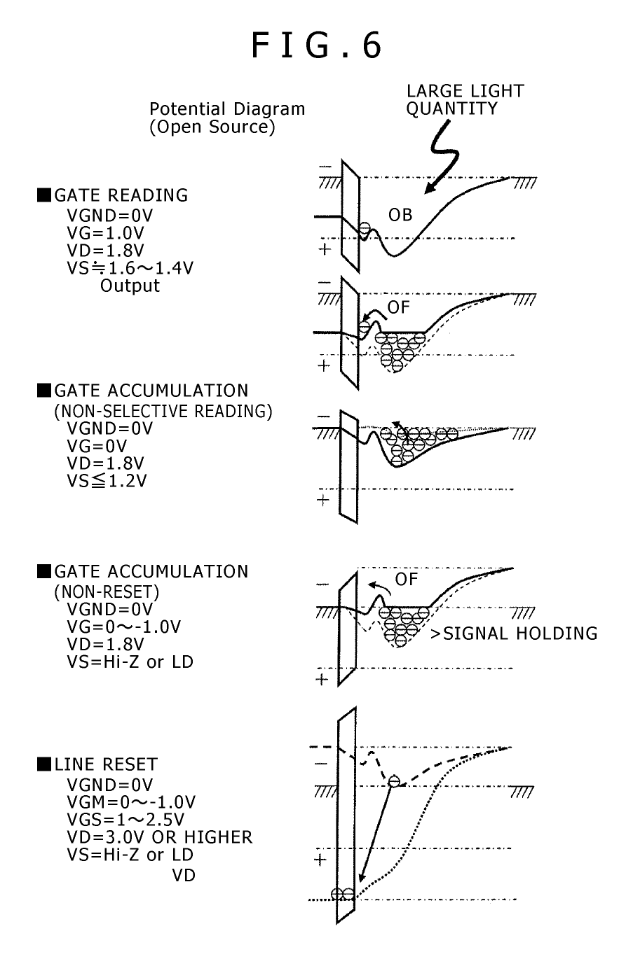

FIG. 6 is a plurality of diagrams showing changes of an electric potential for an electron moving in a semiconductor substrate in a direction perpendicular to the surface of the semiconductor substrate in areas as electric-potential changes accompanying changes of an electric-potential state of the basic structure shown in FIGS. 2A and 2B as the basic structure of a pixel section employed in the solid-state imaging apparatus.

In either of the diagrams, the voltage VGND of a well contact electrode 170 is set at 0 V.

### (i): Gate Read Operation

With the gate voltage VG of the MOS transistor 130 set at 1.0 V and the drain voltage VD of the MOS transistor 130 set at 1.8 V, the source voltage VS of the MOS transistor 130 is set at a magnitude in a range of approximately 1.6 V to about 1.4 V. In this state, the amount of accumulated electric charge composed of electrons decreases and these decreases of the amount of accumulated electric charge modulate the channel electron current flowing from the source to the drain, causing the current to decrease. By measuring the current variations, it is possible to know the changes of the amount of accumulated electric charge composed of electrons. In this case, typically, a voltage equal to the voltage applied to the sub-gate 131S can be applied to the main gate 131M.

### (ii): Gate Electron Accumulation (Non-Read State)

With the gate voltage VG of the MOS transistor 130 set at 0 V and the drain voltage VD of the MOS transistor 130 set at 1.8 V, the source voltage VS of the MOS transistor 130 is set at a magnitude not greater than 1.2 V. In this state, electrons are accumulated inside an electric-potential well created in the vicinity of a semiconductor surface in a gate area between the source of the MOS transistor 130 and the drain of the MOS transistor 130. In this case, typically, a voltage equal to the voltage applied to the sub-gate 131S can be applied to the main gate 131M.

(iii): Gate Electron Accumulation (Non-Reset State and Hard Reset)

With the gate voltage VG of the MOS transistor 130 set at a magnitude in a range of 0 V to 1.0 V and the drain voltage VD of the MOS transistor 130 set at 1.8 V, the source voltage VS of the MOS transistor 130 is set at a magnitude of the Hi−Z (high-impedance state) or a magnitude LD. In this state, accumulated electrons are put in an OF (overflow) state. That is to say, the pixel cell 2A is put in a saturated state. A signal generated at that time is held. In this case, typically, a voltage equal to the voltage applied to the sub-gate 131S can be applied to the main gate 131M.

(iiii): Reset

With the main-gate voltage VGM of the MOS transistor 130 set at a magnitude in a range of 0 V to −1.0 V and the sub-gate voltage VGS of the MOS transistor 130 set at a magnitude in a range of 1 V to −2.5 V, the drain voltage VD of the MOS transistor 130 is set at a magnitude not smaller than 3.0 V. For example, the drain voltage VD is set at 3.7 V. The source voltage VS of the MOS transistor 130 is set at a magnitude of the Hi−Z (high-impedance state) or a magnitude LD. In this state, electrons existing inside an accumulation well are exhausted to the outside by way of the drain electrode 133.

As described above, in this embodiment, during a pixel-signal reset operation, the drain voltage VD or, in some cases, the drain voltage VD and the gate voltage are modulated in order to discharge electrons accumulated in the drain electrode 133 as signal electric charge to the outside.

This reset operation is explained more as follows. In the following description, the reset operation of an ordinary single-carrier CMD is explained for the purpose of comparison.

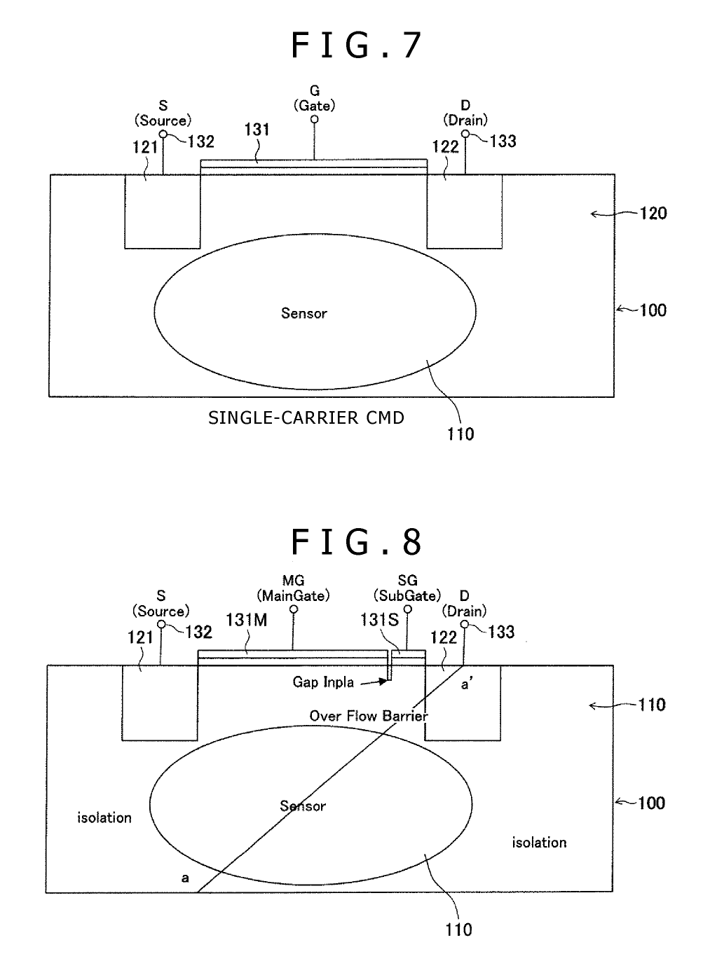

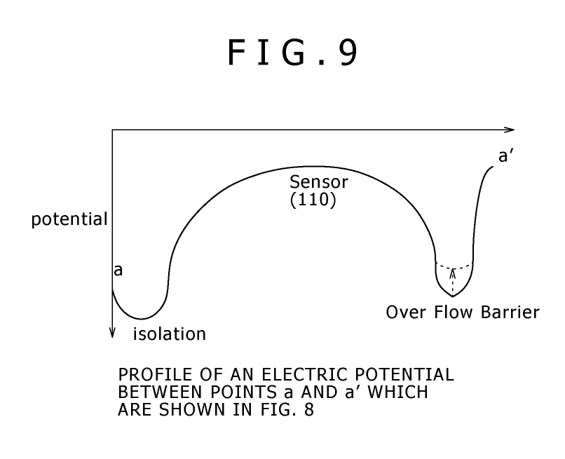

FIG. 7 is a simplified cross-sectional diagram showing a model of an ordinary single-carrier CMD whereas FIG. 8 is a simplified cross-sectional diagram showing a model of the solid-state imaging apparatus 1 according to the embodiment. On the other hand, FIG. 9 is a diagram showing the profile of an electric potential between points a and a′ which are shown in FIG. 8.

In order to make the following description easy to compose, configuration elements employed in the ordinary single-carrier CMD to serve as configuration elements identical with their respective counterpart configuration elements employed in the solid-state imaging apparatus 1 are denoted by the same reference numerals and the same reference symbols as the counterpart configuration elements.

With the single-carrier CMD like the one shown in FIG. 7 adopted as the structure of the CMD, the gate of the read transistor is used for modulating an OFB (overflow barrier) between the sensor and the drain of the transistor in order to lower the barrier. In this way, a reset operation can be carried out.

In addition, if the overflow barrier is high, requiring that a large voltage for the reset operation be large, however, a strong electric field is generated in a pinch-off area at a reset time so that it is quite within the bounds of possibility that a reliability problem is raised.

In the case of the embodiment, on the other hand, the sub-gate 131S for reset operations is newly created on the drain side over the OFB (overflow barrier) as shown in FIG. 8.

An intermediate voltage of typically 1 V or 2 V is applied to the sub-gate 131S on the drain side. The intermediate voltage has a magnitude between a voltage applied to the main gate 131M on the source side and a voltage applied to the drain. The voltage applied to the main gate 131M has a magnitude in a range of 0 to −1.0 V whereas the voltage applied to the drain has a magnitude not smaller than 3 V.

Thus, the voltage applied between the gate and the drain is divided into a voltage between the main gate 131M and the sub-gate 131S and a voltage between the sub-gate 131S and the drain area 122. As a result, the strength of the electric field generated in the pinch-off area beneath the gate is reduced.

In addition, by applying the intermediate voltage of typically 1 V or 2 V to the sub-gate 131S on the drain side, the overflow barrier can be lowered so that it is possible to reduce the magnitude of the drain voltage required in the reset operation.

In the process of separating the main gate 131M and the sub-gate 131S from each other, a gap is created between the main gate 131M and the sub-gate 131S to serve as a gap for preventing a voltage from being applied between the main gate 131M and the sub-gate 131S. With such a structure sustained as it is, a reversed layer is not created in a channel area below the gap. Instead, dips and/or barriers are undesirably formed in the channel area so that it is quite within the bounds of possibility that there is a bad effect on the sensor linearity and the like. In order to solve this problem, in this embodiment, the gap is made narrow in order to reduce an unreversed area and, in addition, ions are injected into the gap in a self-align process or the like. As a result, it is possible to reduce the number of dips in the channel area and the number of barriers in the same area.

In addition, this embodiment is provided with the so-called gamma (γ) characteristic for increasing the degree of modulation and the conversion efficiency at low-illumination times.

On top of that, in this embodiment, the γ characteristic is utilized in the DR (dynamic range).

The γ characteristic of the pixel cell 2A is explained as follows.

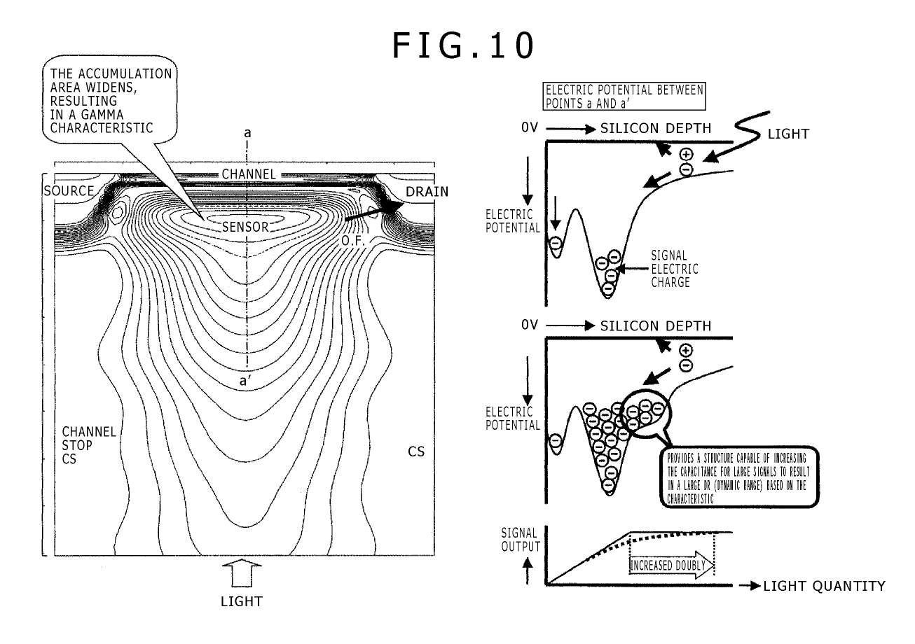

FIG. 10 is a plurality of diagrams showing typical distributions of an electric potential along a line a-a′ shown in FIG. 2A.

As one of characteristics of the double-well structure, the sensor accumulation area has a broad electric-potential shape as shown in FIG. 10. Thus, the capacitance changes in accordance with the magnitude of the signal to result in a nonlinear characteristic referred to as the γ characteristic.

If the single-well structure is provided with the γ characteristic representing the nonlinear characteristic of the linearity, however, the inverse γ correction processing can be carried out and, in addition, a gain of 1 is can be obtained at low-illumination times. This is because, the γ characteristic representing the nonlinear characteristic of the linearity increases the gain at a small-signal time at which a signal is missed. Thus, noises are also compressed at the same time as the signal. As a result, the noises can be reduced.

As described above, in the embodiment, the γ characteristic is utilized deliberately and, as shown in FIGS. 2A and 2B, the structure is provided with a gamma pocket 180 which is a pocket of the n type for accumulating signals as well as a pocket having a depth slightly larger than required.

In this gamma pocket 180, the signal carrier and the signal current are concentrated on one point so that the degree of modulation for small signals is raised.

In addition, an inverse gamma correction processing is carried out by making use of a DSP for performing signal processing at a later stage so that complete noise compression processing can be implemented.

On top of that, as shown in FIG. 10, the pixel cell 2A has a structure capable of increasing the capacitance for large signals to provide a large DR (dynamic range) based on the γ characteristic.

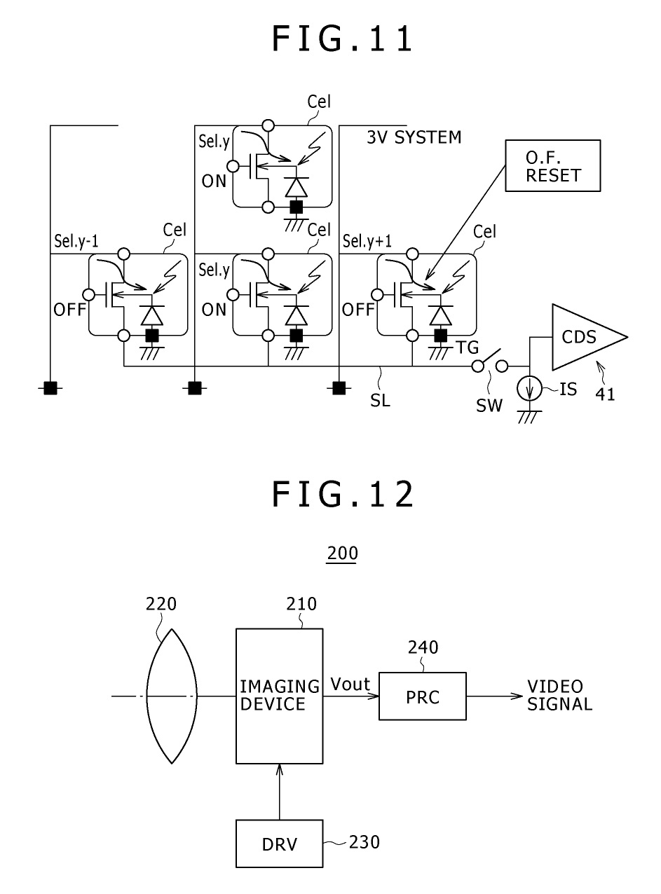

FIG. 11 is a diagram showing a model of the configuration of a signal read processing system according to the embodiment.

The column-direction (X-direction) control circuit 4 includes a CDS circuit 41 for receiving an accumulation signal of the pixel cell 2A put in an off state. The pixel cell 2A transmits the accumulation signal to the CDS circuit 41 by way of a signal transmission line SL and a switch SW. It is to be noted that notation IS shown in the figure denotes a current source used for forming a source follower.

As explained before, the embodiment provides the following effects.

Since a voltage applied between the main gate and the drain is divided into a voltage appearing between the main gate and the sub-gate and a voltage appearing between the sub-gate and the drain, it is possible to reduce the strength of an electric field generated in a pinch-off area below the gate.

By supplying an intermediate electric potential between the main gate and the drain to the sub-gate at a reset time, a gradient can be created between the sensor and the drain at a reset time so that an overflow barrier beneath the sub-gate can be lowered.

By narrowing the gap and carrying out gap implantation, creation of a dip barrier can be restrained so that deterioration of linearity can be avoided.

In addition, a pixel can be configured to include only one transistor having the D (drain)/G (gate)/S (source). Thus, by virtue of good compatibility of logic processes, the increase of a process count representing the number of processes can be minimized in implementation of the pixel.

Contacts can be shared by the drain, the source, the gate and the well so that the layout efficiency can be increased and fine pixels can be implemented.

Since the gate area is large, the number of transistor noises is extremely small.

On top of that, since the entire pixel serves as an accumulation area, the magnitude of a saturated current is large, allowing a large DR (dynamic range).

In addition, since a dark current generated from a boundary surface is discharged to the drain, dark-current image defects of the boundary surface are not generated.

On top of that, the number of noises can be reduced by carrying out an inverse v correction function.

The solid-state imaging apparatus having the characteristics described above can be applied to a digital camera or a video camera as an imaging device of the camera.

3: Camera

FIG. 12 is a block diagram showing a typical configuration of a camera 200 employing the solid-state imaging apparatus according to the embodiment.

As shown in FIG. 12, the camera 200 has an imaging device 210 which is the solid-state imaging apparatus 1 according to the embodiment.

In addition, the camera 200 also employs an optical system 220 for guiding incident light also referred to as image light to a pixel area of the imaging device 210 in order to create a taken image of an imaging aim on the imaging device 210. For example, a lens serving as the optical system 220 guides the light to the imaging device 210 in order to create the image on an imaging surface of the imaging device 210.

On top of that, the camera 200 is also provided with a DRV (driving circuit) 230 for driving the imaging device 210 and a PRC (signal processing circuit) 240 for processing a signal output by the imaging device 210.

The driving circuit 230 includes a timing generator not shown in the figure. The timing generator generates a variety of predetermined timing signals including a start pulse signal and a clock pulse signal which are used for driving circuits included in the imaging device 210. That is to say, the imaging device 210 is driven by the timing signals generated by the timing generator.

In addition, the signal processing circuit 240 carries out signal processing determined in advance on an image signal output by the imaging device 210.

The image signal processed by the signal processing circuit 240 is stored in typically a recording medium. A hard copy of the image signal stored in the recording medium can be produced on a printer or the like. In addition, the image signal processed by the signal processing circuit 240 can also be shown as a moving picture on a monitor such as a liquid-crystal display unit.

As described above, by employing the solid-state imaging apparatus 1 described earlier in a digital still camera to serve as the imaging device 210, a camera having high precision can be implemented.

Technologies adoptable in the present disclosure are by no means limited to the technologies explained in the description of the embodiment.

For example, each numerical value and each material which are used in the present disclosure are by no means limited to respectively the numerical values used in the embodiment and the materials used for making components of the embodiment.

In addition, the embodiment can be changed to any of a variety of modified versions as long as the modified version falls within a range not deviating from essentials of the technologies for the present disclosure.

The present disclosure contains subject matter related to that disclosed in Japanese Priority Patent Application JP 2011-052417 filed in the Japan Patent Office on Mar. 10, 2011, the entire content of which is hereby incorporated by reference.

What is claimed is:

1. A solid-state imaging apparatus comprising
a pixel cell separated by a device separation layer from a group of adjacent pixel cells by taking one pixel cell or a plurality of pixel cells as a unit wherein:
said pixel cell has
a first-conduction well, and
a second-conduction well;
said first-conduction well receives light and has an opto-electrical conversion function of carrying out an opto-electrical conversion process to convert said received light into electric charge as well as an electric-charge accumulation function for accumulating said electric charge;
in said second-conduction well, a transistor is created to serve as a transistor used for detecting said electric charge accumulated in said first-conduction well and provided with a threshold modulation function;
said transistor has a source, a drain as well as a gate electrode created in a channel creation area between said source and said drain; and
said gate electrode is divided into a main gate provided on a side close to said source and a sub-gate provided on a side close to said drain.

2. The solid-state imaging apparatus according to claim 1 wherein:
at least in a reset operation, an intermediate voltage between a voltage applied to said main gate provided on said side close to said source and a voltage applied to said drain is applied to said sub-gate provided on said side close to said drain; and
said reset operation is an operation to discard electric charge to said drain.

3. The solid-state imaging apparatus according to claim 1 wherein said sub-gate is provided over a barrier between said second-conduction well and said drain.

4. The solid-state imaging apparatus according to claim 1 wherein:
a narrow gap is provided between said main gate and said sub-gate; and
ions are injected into a substrate between said gaps.

5. The solid-state imaging apparatus according to claim 1 wherein accumulated electric charge and signal electric charge are the same carrier.

6. The solid-state imaging apparatus according to claim 1 wherein said transistor has functions of a read transistor, functions of a reset transistor and functions of a select transistor.

7. The solid-state imaging apparatus according to claim 1 wherein
said pixel cell is created on a substrate having a first substrate surface side to which light is radiated and a second substrate surface side on which devices are created and separated by said device separation layer from a group of adjacent pixel cells by taking one pixel cell or a plurality of pixel cells as a unit;
in said pixel cell:
said first-conduction well is created on said first substrate surface side; and
said second-conduction well is created on said second substrate surface side;
said first-conduction well receives light from said first substrate surface side and has an opto-electrical conversion function of carrying out an opto-electrical conversion process to convert said received light into electric charge as well as an electric-charge accumulation function for accumulating said electric charge; and
in said second-conduction well, a transistor is created to serve as a transistor used for detecting said electric charge accumulated in said first-conduction well and provided with a threshold modulation function.

8. A camera comprising:
a solid-state imaging apparatus configured to receive light from a first substrate surface side of a substrate; and
an optical system configured to guide incident light to said first substrate surface side of said solid-state imaging apparatus, wherein
said solid-state imaging apparatus has a pixel cell separated by a device separation layer from a group of adjacent pixel cells by taking one pixel cell or a plurality of pixel cells as a unit, and
in said solid-state imaging apparatus,
said pixel cell has
a first-conduction well, and
a second-conduction well,
said first-conduction well receives light and has an opto-electrical conversion function of carrying out an opto-electrical conversion process to convert said received light into electric charge as well as an electric-charge accumulation function for accumulating said electric charge,
in said second-conduction well, a transistor is created to serve as a transistor used for detecting said electric charge accumulated in said first-conduction well and provided with a threshold modulation function,
said transistor has a source, a drain as well as a gate electrode created in a channel creation area between said source and said drain, and
said gate electrode is divided into a main gate provided on a side close to said source and a sub-gate provided on a side close to said drain.

9. The camera according to claim 8 wherein:
at least in a reset operation, an intermediate voltage between a voltage applied to said main gate provided on said side close to said source and a voltage applied to said drain is applied to said sub-gate provided on said side close to said drain; and
said reset operation is an operation to discard electric charge to said drain.

10. The camera according to claim 8 wherein said sub-gate is provided over a barrier between said second-conduction well and said drain.

11. The camera according to claim 8 wherein:
a narrow gap is provided between said main gate and said sub-gate; and
ions are injected into said substrate between said gaps.
